(19) United States
(12) Patent Application Publication
(10) Pub. No.: US 2024/0175747 A1
(43) Pub. Date: May 30, 2024

(54) OPTICAL APPARATUS, ON-BOARD SYSTEM, MOVABLE APPARATUS, CONTROL METHOD OF OPTICAL APPARATUS, AND STORAGE MEDIUM

(71) Applicant: CANON KABUSHIKI KAISHA, Tokyo (JP)

(72) Inventors: RYOTA TANAKA, Kanagawa (JP); YOSHINORI ABE, Saitama (JP)

(21) Appl. No.: 18/494,178

(22) Filed: Oct. 25, 2023

(30) Foreign Application Priority Data
Nov. 30, 2022 (JP) 2022-191145

(51) Int. Cl. G01J 1/44

(52) U.S. Cl. CPC G01J 1/44; G01J 2001/4466

(57) ABSTRACT

An optical apparatus includes a first light receiving unit including a first avalanche photodiode, a second light receiving unit including a second avalanche photodiode whose light receiving surface is shielded from light, and a voltage control unit configured to apply a first reverse bias voltage to the first avalanche photodiode and a second reverse bias voltage to the second avalanche photodiode. The voltage control unit controls the first reverse bias voltage based on the second reverse bias voltage.

### BACKGROUND

### Technical Field

One of the aspects of the embodiments relates to an optical apparatus, an on-board system, a movable apparatus, a control method of the optical apparatus, and a storage medium.

### Description of Related Art

An avalanche photodiode (APD) has conventionally been known as a light receiving element having a multiplication effect. The multiplication factor M of the APD depends on the reverse bias voltage applied to the APD and the temperature. Since the multiplication factor M also depends on individual differences among APDs, the reverse bias voltage is controlled in order to use the APD with a desired multiplication factor M.

Japanese Patent Application Publication No. 2002-324909 discloses a photoelectric detector using the APD that operates stably in an operating region with a high multiplication factor M. Japanese Utility-Model Application Publication No. 61-181336 discloses a photodetection circuit that controls the reverse bias voltage so as to keep the multiplication factor M constant by dividing the breakdown voltage generated at both ends of one light-shielded APD using resistors and by applying it as the reverse bias voltage to the other signal detecting APD.

The photoelectric detector disclosed in Japanese Patent Application Publication No. 2002-324909 needs to detect and adjust the reverse bias voltage in a non-measurement state of the main APD. The photodetection circuit disclosed in Japanese Utility-Model Application Publication No. 61-181336 needs to arduously change circuit constants in order to adjust the reverse bias voltage to a desired multiplication factor M.

### SUMMARY

An optical apparatus according to one aspect of the embodiment includes a first light receiving unit including a first avalanche photodiode, a second light receiving unit including a second avalanche photodiode whose light receiving surface is shielded from light, and a voltage control unit configured to apply a first reverse bias voltage to the first avalanche photodiode and a second reverse bias voltage to the second avalanche photodiode. The voltage control unit controls the first reverse bias voltage based on the second reverse bias voltage. An on-board system and a movable apparatus having the above optical apparatus also constitute another aspect of the embodiment. A control method of the above optical apparatus and a storage medium storing a program that causes a computer to execute the above control method also constitute another aspect of the embodiment.

Further features of the disclosure will become apparent from the following description of embodiments with reference to the attached drawings.

### BRIEF DESCRIPTION OF THE DRAWINGS

FIG. 1 is a schematic diagram of an optical apparatus according to a first embodiment.

FIGS. 2A and 2B are detailed views of the optical apparatus according to the first embodiment.

FIGS. 3A and 3B are detailed diagrams of a TIA circuit according to the first embodiment.

FIG. 4 illustrates a relationship between an ADC output value and reverse bias voltage in the first embodiment.

FIG. 5 illustrates a multiplication factor characteristic of the APD in the first embodiment.

FIG. 6 illustrates actually measured multiplication factor characteristics of two APDs in the first embodiment.

FIG. 7 is a configuration diagram of an on-board system according to each embodiment.

FIG. 8 is a schematic diagram of a vehicle (movable apparatus) according to each embodiment.

FIG. 9 is a flowchart illustrating an operation example of the on-board system in each embodiment.

### DESCRIPTION OF THE EMBODIMENTS

In the following, the term “unit” may refer to a software context, a hardware context, or a combination of software and hardware contexts. In the software context, the term “unit” refers to a functionality, an application, a software module, a function, a routine, a set of instructions, or a program that can be executed by a programmable processor such as a microprocessor, a central processing unit (CPU), or a specially designed programmable device or controller. A memory contains instructions or programs that, when executed by the CPU, cause the CPU to perform operations corresponding to units or functions. In the hardware context, the term “unit” refers to a hardware element, a circuit, an assembly, a physical structure, a system, a module, or a subsystem. Depending on the specific embodiment, the term “unit” may include mechanical, optical, or electrical components, or any combination of them. The term “unit” may include active (e.g., transistors) or passive (e.g., capacitor) components. The term “unit” may include semiconductor devices having a substrate and other layers of materials having various concentrations of conductivity. It may include a CPU or a programmable processor that can execute a program stored in a memory to perform specified functions. The term “unit” may include logic elements (e.g., AND, OR) implemented by transistor circuits or any other switching circuits. In the combination of software and hardware contexts, the term “unit” or “circuit” refers to any combination of the software and hardware contexts as described above. In addition, the term “element,” “assembly,” “component,” or “device” may also refer to “circuit” with or without integration with packaging materials.

Referring now to the accompanying drawings, a detailed description will be given of embodiments according to the disclosure. Corresponding elements in respective figures will be designated by the same reference numerals, and a duplicate description thereof will be omitted.

### First Embodiment

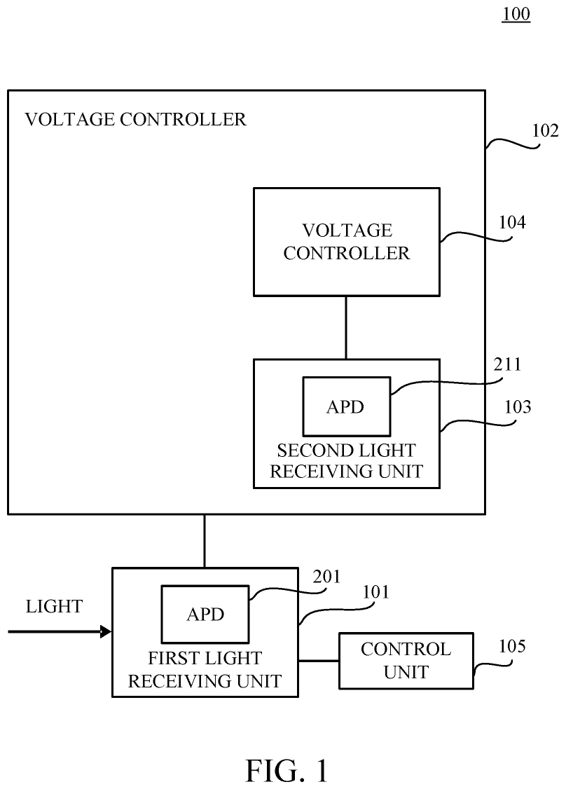

Referring now to FIG. 1, a description will be given of an optical apparatus 100 according to a first embodiment. FIG. 1 is a schematic diagram of an optical apparatus 10 according to this embodiment. The optical apparatus 100 includes a first light receiving unit 101 including an APD (first avalanche photodiode) 201, and a voltage controller (first voltage control unit) 102 configured to control the reverse bias voltage applied to the APD 201. The voltage controller 102 includes a second light receiving unit 103 that includes an APD (second avalanche photodiode) 101, and a voltage controller (second voltage control unit) 104 configured to control the reverse bias voltage applied to the APD 211. The voltage controllers 102 and 104 constitute a voltage control unit configured to apply the first reverse bias voltage to the APD 201 and applies the second reverse bias voltage to the APD 211.

The APD 201 is a main (system) APD, and signal light and background light (disturbance light) enter the light receiving surface of the APD 201. On the other hand, the APD 211 is a dark (system) APD, and the light receiving surface of the APD 211 is shielded from light by a light shielding unit. The light shielding unit for the APD 211 can be realized by housing the entire package of the APD 211 in a box that shields light having a wavelength to which the APD 211 is sensitive. Alternatively, in a case where the package of the APD 211 has a window, this may be realized by attaching a cover to the window that blocks the light having the wavelength to which the APD 211 is sensitive. The cover can be formed by directly depositing on the window material a film that blocks the light having the wavelength to which the APD 211 is sensitive. Alternatively, the cover can use a light shielding body placed directly on the light receiving unit of the light receiving board of the APD 211. Alternatively, a film that blocks the light having the wavelength to which the APD 211 is sensitive may be deposited on the light receiving unit in the manufacturing process of the light receiving board of the APD 211.

The optical apparatus 100 further includes a control unit 105 configured to acquire distance information on an object based on the output of the first light receiving unit 101. Due to this configuration, the optical apparatus 100 is used, for example, as a Light Detection and Ranging (LIDAR) that calculates a distance from the time and phase from when the object is irradiated with light from a light source to when reflected light is received.

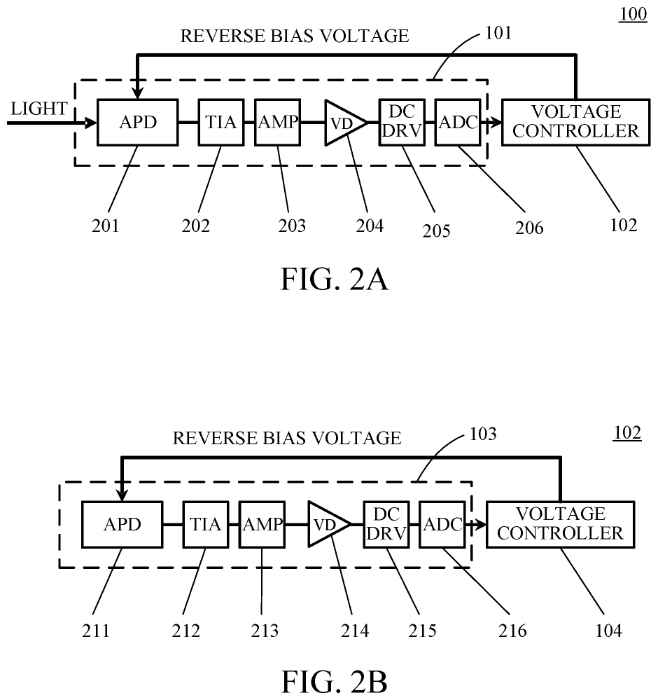

Referring now to FIGS. 2A and 2B, a detailed description will be given of the configuration of the optical apparatus 100. FIGS. 2A and 2B are detailed views of the optical apparatus 100. As illustrated in FIG. 2A, a Trans-Impedance Amplifier (TIA) 202 is connected to the backside of the APD 201. An AMP (post amplifier) 203, a VD (50 Ω DC matching voltage divider) 204, a DCdrv (DC coupled differential A/D driver) 205, an ADC (A/D converter) 206, and the voltage controller 102 are connected in this order to the backside of the TIA 202.

Since the output current of the APD 201 cannot be directly measured, the output current of the APD 201 is measured as follows. The output current of the APD 201 is converted into the voltage by the TIA 202 and amplified by the AMP 203. The output of the AMP 203 is matched to 50 [Ω] and is supplied to the ADC 206 via the VD 204 and the DCdrv 205. The data digitally converted by the ADC 206 receives signal processing by the voltage controller 102. The voltage controller 102 detects a signal (output value of the ADC 206) corresponding to the output current of the APD 201. The voltage controller 102 sets the reverse bias voltage of the APD 201.

Similarly, as illustrated in FIG. 2B, a Trans-Impedance Amplifier (TIA) 212 is connected the backside of the APD 211. An AMP (post amplifier) 213, a VD (50 Ω DC matching voltage divider) 214, a DCdrv (DC-coupled differential A/D driver) 215, an ADC (A/D converter) 216, and a voltage controller 104 are connected in this order to the backside of the TIA 212.

Since the output current of the APD 211 cannot be directly measured, the output current of the APD 211 is measured as follows. The output current of the APD 211 is converted into the voltage by the TIA 212 and amplified by the AMP 213. The output of the AMP 213 is matched to 50 [Ω] and is supplied to the ADC 216 via the VD 214 and the DCdrv 215. The data digitally converted by the ADC 216 receives signal processing by the voltage controller 104. The voltage controller 104 detects a signal (output value of the ADC 216) corresponding to the output current of the APD 211. The voltage controller 104 sets the reverse bias voltage of the APD 211. Thus, the output current of the APD 211 is also measured by detecting a signal corresponding to the output current of the APD 211 with the voltage controller 104, similarly to the APD 201 (main system).

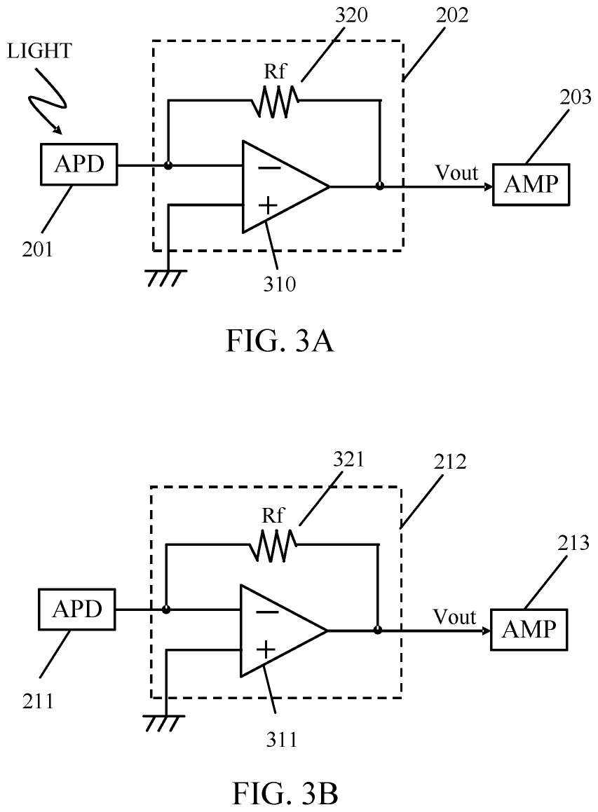

Referring now to FIGS. 3A and 3B, a detailed description will be given of circuits of the TIAs 202 and 212. FIG. 3A is a circuit diagram of the TIA 202. FIG. 3B is a circuit diagram of the TIA 212. In a case where the TIA 202 is configured as an inverting amplifier circuit, an anode of the APD 201 is connected to an inverting input terminal of an operational amplifier 310, as illustrated in FIG. 3A. A feedback resistor Rf320 is inserted between the inverting input terminal and an output terminal of an operational amplifier 310. A non-inverting input terminal of operational amplifier 310 is grounded. The operational amplifier 310 may be driven by dual power supplies with a voltage applied to the non-inverting input terminal instead of being driven by a single power supply as described above. In a case where the output value (output signal) of the APD 201 is large, the voltage may be converted using only a resistor without using the operational amplifier 310.

The circuit of the TIA212 is similar to the TIA202. As illustrated in FIG. 3B, the anode of the APD 211 is connected to the inverting input terminal of the operational amplifier 311. A feedback resistor Rf321 is inserted between the inverting input terminal and the output terminal of the operational amplifier 311. A non-inverting input terminal of the operational amplifier 311 is grounded. The operational amplifier 311 may be driven by dual power supplies with a voltage applied to the non-inverting input terminal instead of being driven by single power supply. In a case where the output value (output signal) of the APD 211 is large, the voltage may be converted using only a resistor without using the operational amplifier 311.

In the TIA circuit, the output voltage VOUT of the operational amplifier is expressed by the following equation (1):

$${V}_{O U T} = \frac{- {R}_{f} {I}_{A P D}}{1 - A {( \frac{{V}_{A P D}}{{V}_{B R}} )}^{n}} \qquad ( 1 )$$

where V_{APD} is the reverse bias voltage of the APD, I_{APD} is the current of the APD, V_{BR} is the breakdown voltage of the APD, and A is a coefficient according to an ionization ratio k of holes and electrons in the APD and is expressed as A=ln(k)/(k−1).

The ionization rate ratio k depends on the material and the electric field intensity in the depletion layer, and is therefore a function of the reverse bias voltage of the APD. In a case where the multiplication factor M of APD is high, k approaches 1, so A≈1. In equation (1), n is a value determined by the element structure and material of the APD. V_{OUT} is amplified by R_{f} times as large as I_{APD} and becomes an inverted value. The TIA circuit is not limited to an inverting amplifier circuit, but may be a non-inverting amplifier circuit. In that case, only the feedback resistance Rf is changed, and V_{OUT} is basically expressed by the above equation (1).

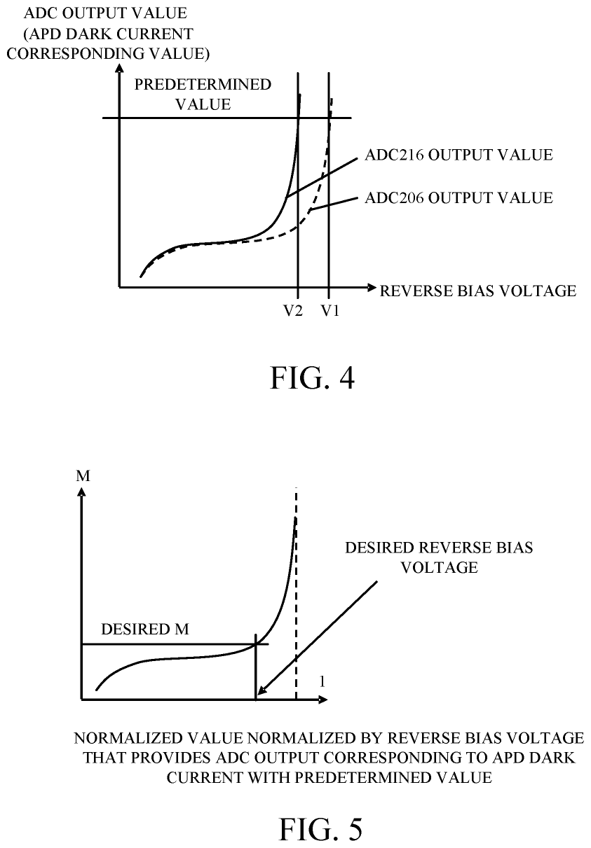

Referring now to FIG. 4, a description will be given of an adjusting method of the reverse bias voltage so that the multiplication factor of the APD 201 becomes the desired multiplication factor M. FIG. 4 illustrates ae relationship between ADC output value and reverse bias voltage. In FIG. 4, the vertical axis represents the ADC output value (APD dark current corresponding value), and the horizontal axis represents the reverse bias voltage of the ADC. In FIG. 4, a broken line indicates a relationship between the output value of the ADC 206 and the reverse bias voltage of the APD 201, and a solid line indicates a relationship between the output value of the ADC 216 and the reverse bias voltage of the APD 211.

Now assume that the reverse bias voltage of the APD 201 at which the output value of the ADC 206 becomes a predetermined value is V1, and the reverse bias voltage of the APD 211 at which the output value of the ADC 216 becomes a predetermined value is V2. The voltage controller 104 measures the reverse bias voltage V2. As described above, since the APD 211 is shielded from light so that no light enters the light receiving surface, the output value of the ADC 216 corresponds to the dark current of the APD 211. On the other hand, since the signal light and background light (disturbance light) enter the light receiving surface of the APD 201, the reverse bias voltage V1 of the APD 201, which is the same as a predetermined value corresponding to the dark current of the APD 211, cannot be measured using the output value of the ADC 206. Therefore, this embodiment calculates the reverse bias voltage V1 of the APD 201 based on the reverse bias voltage V2 of the APD 211.

Other circuits except the APDs 201 and 101 are the same. However, if there are individual differences between the APD 201 and the APD 211, the reverse bias voltage characteristics between the output value of the ADC 206 and the output value of the ADC 216 may not match, as illustrated in FIG. 4, even in a case where no light enters the APD 201. In that case, before the reverse bias voltage of the APD 201 is adjusted to give the desired multiplication factor M, while the light receiving surface of the APD 201 is shielded from light, the voltage controller 102 measures the reverse bias voltage V1 of the APD 201, and the voltage controller 104 measures the reverse bias voltage V2 of the APD 211. From these measurement results, a ratio Vratio between the reverse bias voltages V1 and V2 is calculated. Based on the ratio Vratio, the reverse bias voltage V2 is measured at a timing to adjust the reverse bias voltage of the APD 201 to give the desired multiplication factor M while light enters the APD 201, and the reverse bias voltage V1 is calculated using the measured reverse bias voltage V2.

Referring now to FIG. 5, a description will be given of a method of adjusting the reverse bias voltage of the APD 201 using the reverse bias voltage V2 so that the APD 201 has a desired multiplication factor M. FIG. 5 illustrates the multiplication factor characteristic of the APD (characteristic diagram illustrating a relationship between the multiplication factor of the APD and the reverse bias voltage). In FIG. 5, the vertical axis represents the multiplication factor M of the APD, and the horizontal axis represents a normalized value normalized by the reverse bias voltage V2 at which the output value of the ADC 216 corresponding to the dark current of the APD has a predetermined value.

The voltage controller 102 sets a reverse bias voltage such that the APD 201 has the desired multiplication factor M based on the reverse bias voltage V1 and the multiplication factor characteristic illustrated in FIG. 5. More specifically, the voltage controller 102 reads the normalized value (reverse bias voltage normalized value) that provides the desired multiplication factor M from the multiplication factor characteristic, and multiplies the normalized value by the reverse bias voltage V1 to acquire the desired reverse bias voltage.

This embodiment utilizes the characteristic of the APD 201 as the multiplication factor characteristic, but this embodiment is not limited to this example, and this embodiment may utilize the multiplication factor characteristic of the APD 211. As long as the multiplication factor characteristic falls within the absolute rated temperature range, there are virtually no individual differences or temperature dependences, so if the model number is the same, the multiplication factor characteristic of another APD that is neither APD201 nor APD211 may be acquired and used as a representative value. Since the multiplication factor characteristic of each APD does not completely the same, the characteristic of the APD 201 may be utilized in order to reduce the setting shift from the reverse bias voltage that provides the desired multiplication factor M.

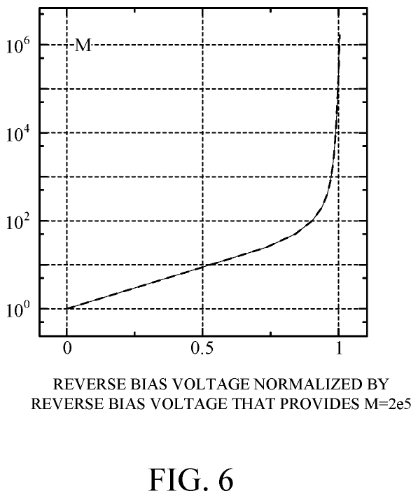

FIG. 6 illustrates an example of an actual measurement result of the multiplication factor characteristics of two APDs of the same model number. A description of the measurement method will be omitted. In FIG. 6, the vertical axis represents the multiplication factor M, and the horizontal axis represents the normalized value normalized by the reverse bias voltage in a case where the ADC output value with the multiplication factor M of 2e5 (2×10⁵) is set as a predetermined value. The multiplication factor characteristics (broken line and solid line) of the two APDs substantially overlap each other. From this fact, it is understood that the characteristic of any APD of the same model number may be used to set the multiplication factor characteristic.

For better understanding, this embodiment uses the reverse bias voltage V1 and the multiplication factor characteristic in adjusting the reverse bias voltage so that the APD 201 has the desired multiplication factor M. However, it is not essential to use at least one of the reverse bias voltage V1 or the multiplication factor characteristic, and the reverse bias voltage of the APD 201 may be set based on the reverse bias voltage V2.

The predetermined value will now be described. The predetermined value is an output value of the ADC 206 of the APD 211 in which a ratio of the output value of the ADC 216 to the output value of the ADC 216 (at V_{APD}=0 [V]), which corresponds to the output current with the multiplication factor M=1 of the APD 211, that is, the multiplication factor M of the APD 211 is larger than at least 2e5. However, if the multiplication factor is small, a setting shift from the reverse bias voltage of the APD 201 that provides the desired multiplication factor M becomes large, and if the multiplication factor is large, the setting shift from the reverse bias voltage of the APD 201 that provides the desired multiplication factor M becomes small. Therefore, the desired multiplication factor M may be set according to the permissible setting shift, and is not limited to M=2e5.

A description will now be given of control timing. The reverse bias voltage V2 may be measured at which the output value of the ADC 216 of the APD 211 (the value corresponding to the dark current of the APD 211) has the predetermined value at a timing to adjust the reverse bias voltage of the APD 201 to give the desired multiplication factor M. As illustrated in FIGS. 2A and 2B, in a case where the APD 201 and APD 211 systems are independent of each other, the reverse bias voltage V2 can be measured and acquired without interrupting the operation of the main APD 201. Based on the acquired reverse bias voltage V2, the reverse bias voltage to be applied to the main system APD 201 is adjusted to a reverse bias voltage at which the APD 201 has a desired multiplication factor M.

### Second Embodiment

A description will be given of a second embodiment. In the optical apparatus 10 according to the first embodiment, the two APDs 201 and 211 are configured in different packages. However, it is difficult to manufacture APDs having the same characteristics, and as illustrated in FIG. 4, there are individual differences among APDs. In order to make the characteristics of APDs 201 and 211 as equal as possible, APDs 201 and 211 may be disposed on the same wafer substrate. In that case, the characteristics of the reverse bias voltages V1 and V2 are equal to each other in comparison with the characteristics in a case where they are housed in separate packages. Therefore, it is unnecessary to calculate the ratio Vratio and V1=V2 may be set. Since the multiplication factor characteristics are also substantially equal between the APD 201 and the APD 211, the reverse bias voltage of the APD 201 may be adjusted to obtain the desired multiplication factor M using the characteristic of the APD 201 or the APD 211.

### On-Board System (In-Vehicle System)

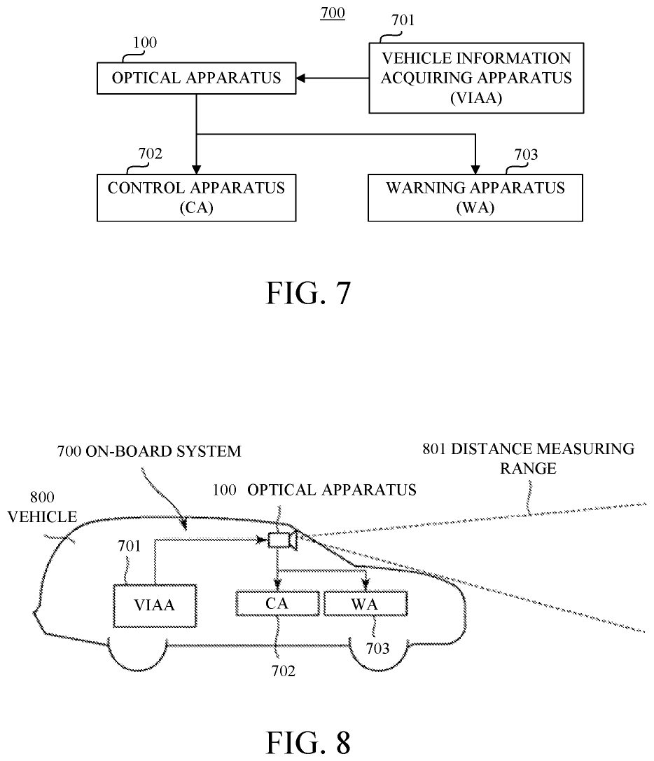

Referring now to FIGS. 7 to 9, a description will be given of an on-board system (driving support apparatus) 700 including the optical apparatus 100 according to each embodiment. FIG. 7 is a configuration diagram of the on-board system 700. The on-board system 700 is a system held by a movable apparatus such as a vehicle, and configured to support driving (maneuvering) based on distance information on an object such as an obstacle and pedestrian around the vehicle acquired by the optical apparatus 100. FIG. 8 is a schematic diagram of a vehicle 800 as a movable apparatus including the on-board system 700. While FIG. 8 illustrates a distance measuring range (detection range) 801 of the optical apparatus 100 is set to the front side of the vehicle 800, the distance measuring range 801 may be set to the back or lateral side of the vehicle 800.

As illustrated in FIG. 7, the on-board system 700 includes the optical apparatus 100, a vehicle information acquiring apparatus 701, a control apparatus (control unit or electronic control unit (ECU)) 702, and a warning apparatus (warning unit) 703. In the on-board system 700, the control unit 105 in the optical apparatus 100 has a function as a distance acquiring unit (acquiring unit) and a collision determining unit (determining unit). If necessary, a distance acquiring unit and a collision determining unit may be provided to the on-board system 700 separately from the control unit 105, and each may be provided outside the optical apparatus 100 (for example, inside the vehicle 800). Alternatively, the control apparatus 702 may be used as the control unit 105.

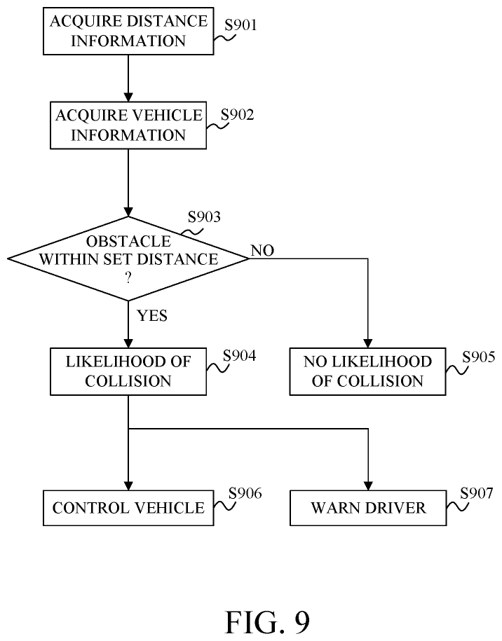

FIG. 9 is a flowchart illustrating an example of the operation of the on-board system 700. The operation of the on-board system 700 will be described below according to this flowchart.

First, in step S901, a light source unit (not illustrated) of the optical apparatus 100 illuminates an object around the vehicle, and the control unit 105 acquires the distance information on the object based on a signal output by the first light receiving unit 101 by receiving reflected light from the object. In step S902, the vehicle information acquiring apparatus 701 acquires vehicle information including the vehicle speed, yaw rate, steering angle, etc. of the vehicle. In step S903, the control unit 105 determines whether the distance to the object is within a preset distance range using the distance information acquired in step S901 and the vehicle information acquired in step S902.

Thereby, whether an object exists within a set distance around the vehicle can be determined, and the likelihood of collision between the vehicle and the object can be determined. Steps S901 and S902 may be performed in the reverse order or in parallel. In step S903, the control unit 105 determines whether the object (obstacle) exists within the set distance. If the object exists within the set distance, the flow proceeds to step S904, and the control unit 105 determines that there is a “likelihood of collision.” On the other hand, if there is no object within the set distance, the flow proceeds to step S905, and the control unit 105 determines that there is “no likelihood of collision.”

Next, in a case where the control unit 105 determines that there is a “likelihood of collision,” it notifies (sends) the determination result to the control apparatus 702 and warning apparatus 703. In step S906, the control apparatus 702 controls the vehicle based on the determination result by the control unit 105. In step S907, the warning apparatus 703 issues a warning to the user (driver and passenger) of the vehicle based on the determination result by the control unit 105. The determination result may be notified to at least one of the control apparatus 702 and the warning apparatus 703.

The control apparatus 702 can control the movement of the vehicle by outputting a control signal to a driving unit (engine, motor, etc.) of the vehicle. For example, the control apparatus 702 performs control such as applying a brake in a vehicle, releasing an accelerator, turning a steering wheel, generating a control signal for generating a braking force in each wheel, and suppressing an output of an engine or a motor. The warning apparatus 703 warns the user, for example, by emitting a warning sound, displaying warning information on a screen of a car navigation system, vibrating the seat belt or steering wheel, or the like.

As described above, the on-board system 700 can detect objects, measure a distance to the object through the above processing, and avoid collision between the vehicle and the object. In particular, applying the optical apparatus 100 according to each embodiment to the on-board system 700 can achieve high distance measuring accuracy, thus can detect an object, and determine collision with high accuracy.

This embodiment applies the on-board system 700 to driving support (collision damage reduction), but the on-board system 700 can be applied to cruise control (including adaptive cruise control function), automatic driving, etc. The on-board system 700 can be applied not only to vehicles such as automobiles, but also to moving apparatuses such as ships, aircraft, and industrial robots. The embodiment is applicable not only to moving apparatuses but also to various apparatuses that utilize object recognition, such as intelligent transportation systems (ITS) and monitoring systems.

### Other Embodiments

Embodiment(s) of the disclosure can also be realized by a computer of a system or apparatus that reads out and executes computer-executable instructions (e.g., one or more programs) recorded on a storage medium (which may also be referred to more fully as a ‘non-transitory computer-readable storage medium’) to perform the functions of one or more of the above-described embodiment(s) and/or that includes one or more circuits (e.g., application specific integrated circuit (ASIC)) for performing the functions of one or more of the above-described embodiment(s), and by a method performed by the computer of the system or apparatus by, for example, reading out and executing the computer-executable instructions from the storage medium to perform the functions of one or more of the above-described embodiment(s) and/or controlling the one or more circuits to perform the functions of one or more of the above-described embodiment(s). The computer may comprise one or more processors (e.g., central processing unit (CPU), micro processing unit (MPU)) and may include a network of separate computers or separate processors to read out and execute the computer-executable instructions. The computer-executable instructions may be provided to the computer, for example, from a network or the storage medium. The storage medium may include, for example, one or more of a hard disk, a random-access memory (RAM), a read-only memory (ROM), a storage of distributed computing systems, an optical disc (such as a compact disc (CD), digital versatile disc (DVD), or Blu-ray Disc (BD)™), a flash memory device, a memory card, and the like.

While the disclosure has been described with reference to embodiments, it is to be understood that the disclosure is not limited to the disclosed embodiments. The scope of the following claims is to be accorded the broadest interpretation so as to encompass all such modifications and equivalent structures and functions.

In a case where an APD system different from the main system is used, each embodiment does not need a multiplication factor characteristic for each individual and each environmental temperature, and can adjust the main APD to the reverse bias voltage that provides the desired multiplication factor M using only a representative multiplication factor characteristic without changing the main system to a non-measurement state. Therefore, each embodiment can provide an optical apparatus, an on-board system, a movable apparatus, a method for controlling the optical apparatus, and a storage medium, each of which can easily control a reverse bias voltage so that the multiplication factor of the avalanche photodiode becomes a desired multiplication factor.

This application claims the benefit of Japanese Patent Application No. 2022-191145, filed on Nov. 30, 2022, which is hereby incorporated by reference herein in its entirety.

What is claimed is:

1. An optical apparatus comprising:
a first light receiving unit including a first avalanche photodiode;
a second light receiving unit including a second avalanche photodiode whose light receiving surface is shielded from light; and
a voltage control unit configured to apply a first reverse bias voltage to the first avalanche photodiode and a second reverse bias voltage to the second avalanche photodiode,
wherein the voltage control unit controls the first reverse bias voltage based on the second reverse bias voltage.

2. The optical apparatus according to claim 1, wherein the voltage control unit applies the second reverse bias voltage to the second avalanche photodiode so that an output current of the second light receiving unit is larger than a predetermined value.

3. The optical apparatus according to claim 1, wherein the voltage control unit determines a reverse bias voltage using a characteristic showing a relationship between a multiplication factor and the reverse bias voltage of an avalanche photodiode and the second reverse bias voltage.

4. The optical apparatus according to claim 3, wherein the characteristic is a characteristic of the first avalanche photodiode.

5. The optical apparatus according to claim 3, wherein the voltage control unit determines the first reverse bias voltage using a measurement result measured while a light-receiving surface of the first avalanche photodiode is shielded from light.

6. The optical apparatus according to claim 1, wherein the first avalanche photodiode and the second avalanche photodiode are disposed on the same substrate.

7. The optical apparatus according to claim 1, wherein the voltage control unit includes:
a first voltage control unit configured to control the first reverse bias voltage;
a second voltage control unit configured to control the second reverse bias voltage,
wherein the first voltage control unit includes the second voltage control unit and the second light receiving unit.

8. The optical apparatus according to claim 1, wherein the voltage control unit adjusts a multiplication factor of the first avalanche photodiode by controlling the first reverse bias voltage.

9. The optical apparatus according to claim 1, further comprising an acquiring unit configured to acquire distance information on an object based on an output of the first light receiving unit.

10. An on-board system comprising:
the optical apparatus according to claim 9; and
a determining unit configured to determine a likelihood of collision between a vehicle and the object based on the distance information on the object.

11. A movable apparatus comprising the optical apparatus according to claim 9, wherein the movable apparatus is movable while holding the optical apparatus.

12. A control method of an optical apparatus that includes a first avalanche photodiode and a second avalanche photodiode whose light-receiving surface is shielded from light, the control method comprising the steps of:
acquiring a second reverse bias voltage to be applied to the second avalanche photodiode; and
controlling a first reverse bias voltage applied to the first avalanche photodiode based on the second reverse bias voltage.

13. A non-transitory computer-readable storage medium storing a program for causing a computer to execute the control method according to claim 12.
